(19) United States
(12) Patent Application Publication
(10) Pub. No.: US 2009/0179712 A1
(43) Pub. Date: Jul. 16, 2009

(54) Electric apparatus

(75) Inventors: Tae Sun Jang, Suwon-si (KR); Hark Byeong Park, Suwon-si (KR); Jong Sung Lee, Seoul (KR); Hyung Geun Kim, Yongin-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co.. Ltd., Suwon-si (KR)

(21) Appl. No.: 12/285,230

(22) Filed: Sep. 30, 2008

(30) Foreign Application Priority Data
Jan. 14, 2008 (KR) 10-2008-0004153

(51) Int. Cl. H03H 7/38

(52) U.S. Cl. 333/33

(57) ABSTRACT

An electric apparatus capable of stably transmitting signals in a high frequency band (high speed signals) by preventing distortion of a signal waveform through impedance control is disclosed. The electric apparatus includes a case having a signal line which transmits signals between electronic parts, a dielectric deposited on the case and the signal line, and a ground portion disposed on the dielectric.

### CROSS-REFERENCE TO RELATED APPLICATIONS

This application claims the priority benefit of Korean Patent Application No. 2008-0004153, filed on Jan. 14, 2008 in the Korean Intellectual Property Office, the disclosure of which is incorporated herein by reference.

### BACKGROUND

1. Field

The present invention relates to an electric apparatus, and more particularly to an electric apparatus capable of stably transmitting signals in a high frequency band (high speed signals) by preventing distortion of a signal waveform through impedance control.

2. Description of the Related Art

Generally, electronic parts such as various types of chips are mounted on a printed circuit board (PCB). The printed circuit board having a circuit is mounted in a product, device, etc.

Recently, a portion of an electric circuit to be mounted on the printed circuit board is mounted on a case (typically made of a nonconductor such as plastic) of a product, device, etc. to realize light, thin, short, and small products, devices, etc.

Using current technology, a high speed integrated circuit (IC) such as a digital signal processor (DSP) and a memory is realized in the electric circuit mounted on the case in the form of a normal signal circuit or a differential signal circuit as shown in FIGS. 1A and 1B.

A left diagram of FIG. 1A represents a top view of a normal signal circuit, and a right diagram of FIG. 1A represents a longitudinal cross-sectional view taken along a dotted line of the left diagram.

A power supply 3, a signal line 2, a load 5 and a ground line 4 are arranged on a case 1. A signal coming from the power supply 3 is transmitted to the load 5 along the signal line 2. The signal having passed through the load 5 returns to the power supply 3 through the ground line 4. In the right diagram of FIG. 1A, W denotes a line width of the signal line 2 or the ground line 4, and S denotes a line distance between the signal line 2 and the ground line 4.

A left diagram of FIG. 1B represents a top view of a differential signal circuit, and a right diagram of FIG. 1B represents a longitudinal cross-sectional view taken along a dotted line of the left diagram.

A power supply 3, a first signal line 2a, a load 5 and a second signal line 2b are arranged on a case 1. A virtual ground is produced on a line 6 (a dot-dot-dashed line in the figure), which connects the power supply 3 and the load 5. In this case, a D+ signal (e.g., +1V) is transmitted along the first signal line 2a and a D− signal (e.g., −1V) is transmitted along the second signal line 2b. The D+ signal coming from the power supply 3 is transmitted to the load 5 along the first signal line 2a. The signal, which has passed through the load 5, returns to the power supply 3 through a virtual ground line 6. Further, the D− signal coming from the power supply 3 is transmitted to the load 5 along the second signal line 2b. The signal which has passed through the load 5 returns to the power supply 3 through the virtual ground line 6.

In case of the differential signal circuit shown in FIG. 1B, signals having different directions (signs) are transmitted through the first and second signal lines 2a and 2b to cancel the noise therebetween, thereby obtaining more stable signals than the normal signal circuit.

Hereinafter, the concept of the impedance and the characteristics according to the frequency are explained in brief.

Generally, the impedance represents a ratio of current to voltage at a specific position of the circuit and may be obtained by the following equation 1.

$${Z}_{0} = R + j ω L + \frac{1}{j ω C} \qquad [ Eq . 1 ]$$

where R represents a resistance component, L represents an inductance component, C represents a capacitance component, and ω represents a frequency.

As represented by Eq. 1, the impedance value is determined by the resistance component by a low frequency value (small value of ω) in a low-speed signal, whereas the impedance value is determined by the inductance component by a high frequency value (large value of ω) in a high speed signal. Particularly, in a high frequency band, since an inductance component of a return path is a main factor to determine the impedance value, the impedance may be obtained by the following equation 2.

Z₀≈jωL [Eq. 2]

FIGS. 2A and 2B are graphs showing measurement results of impedances of the normal signal circuit and the differential signal circuit mounted on the conventional cases, respectively.

As seen from the measurement results of impedances shown in FIGS. 2A and 2B, a minimum impedance 133 Ohm (Ω) is obtained with a line width W and a line distance S currently used in the circuit. Required impedances of 100Ω for a universal serial bus (USB) and 50Ω for the normal circuit cannot be satisfied by this value.

In this case, the impedance can be reduced by decreasing the line distance S or increasing the line width W. However, process restrictions prevent continuous reduction of the line distance S. Further, production of light, thin, short, and small products, which is the reason for mounting the circuit on the case, cannot be achieved with an increased line width W. Accordingly, impedance control is still difficult and there is a limit in mounting a high speed signal circuit on the case.

In the high speed signal (high frequency band) differently from the low speed signal (low frequency band), an impedance difference may be generated between an input terminal and an output terminal when different circuit lines are interconnected. In this case, as shown in FIG. 3A, signal distortion is generated due to signal reflection in both input and output waveforms (a solid line denotes an input waveform and a dotted line denotes an output waveform). Accordingly, signal integrity (SI) and electromagnetic interference (EMI) characteristics are deteriorated, thereby causing malfunction of the circuit and failure of a circuit device. On the contrary, as shown in FIG. 3B, if there is no impedance difference between the input terminal and the output terminal, the input and output waveforms are kept nearly uniform. Thus, in the high frequency (high speed signal) circuit, impedance control (impedance matching) between the circuit lines is required to prevent malfunction of the circuit and obtain a stable waveform.

### SUMMARY

The present invention solves the above problems. It is an aspect of the invention to provide an electric apparatus capable of stably transmitting a signal in a high frequency band (high speed signal) by preventing distortion of a signal waveform through impedance control.

In accordance with an aspect of the invention, there is provided an electric apparatus including a case having a signal line which transmits signals between electronic parts; a dielectric deposited on the case and the signal line; and a ground portion disposed on the dielectric, wherein the ground portion is a predetermined distance from the signal line.

The dielectric has a surface and the ground portion may be disposed on the entire surface of the dielectric.

The predetermined distance may provide an impedance of about 50 ohms.

The predetermined distance may provide an impedance of about 100 ohms.

In accordance with another aspect of the invention, there is provided an electric apparatus including a case having a signal line which transmits signals between electronic parts; a dielectric deposited on the case and the signal line; and a ground portion which is disposed on the dielectric and which has a plurality of holes.

The holes may have a width and the width of the holes may be greater than the width of the signal line.

The holes may have a width and the width of the holes may be perpendicular to an arrangement direction of the signal line.

The holes may be non-parallel to an arrangement direction of the signal line.

The holes may have a longitudinal width and the longitudinal width of the holes may be adjusted to control impedance of the electric apparatus.

The holes may have a longitudinal width and the longitudinal width of the holes may be adjusted to control impedance of the electric apparatus to provide an average impedance of 50 ohms.

In an aspect of the present invention, there is an effect of stably transmitting a signal in a high frequency band (high speed signal) by preventing distortion of a signal waveform through impedance control of the electric apparatus.

Further, in an aspect of the present invention, there is an effect of providing light, thin, short, and small products by realizing a high speed circuit on a case of a product.

### BRIEF DESCRIPTION OF THE DRAWINGS

These and/or other aspects, features, and advantages of exemplary embodiments of the invention will become apparent and more readily appreciated from the following description of exemplary embodiments, taken in conjunction with the accompanying drawings, of which:

FIGS. 1A and 1B illustrate a normal signal circuit and a differential signal circuit mounted on conventional cases, respectively;

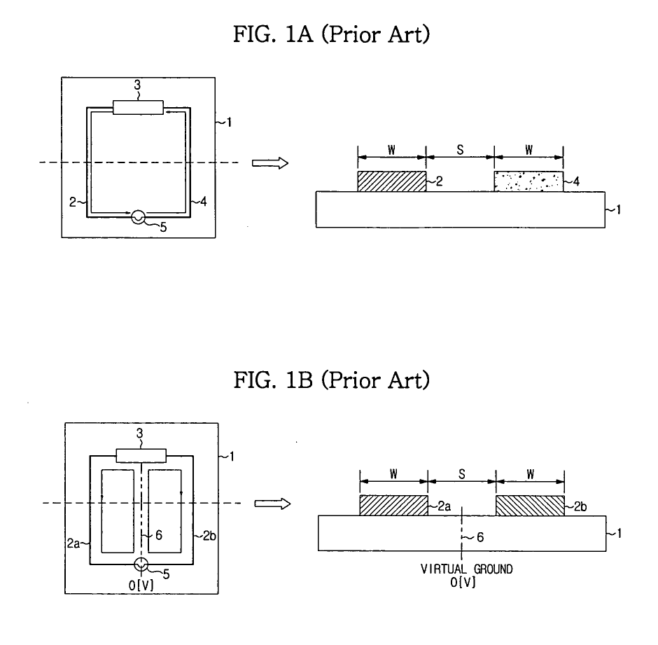

FIGS. 2A and 2B are graphs showing measurement results of impedances of the normal signal circuit and the differential signal circuit mounted on the conventional cases, respectively;

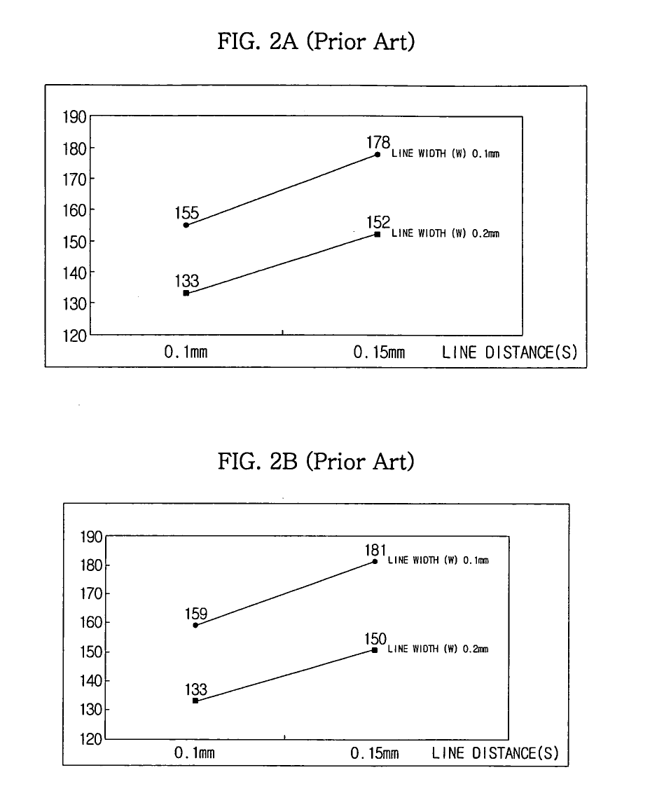

FIG. 3A is a graph showing input and output waveforms when there is an impedance difference between the input terminal and the output terminal, and FIG. 3B is a graph showing input and output waveforms when there is no impedance difference between the input terminal and the output terminal;

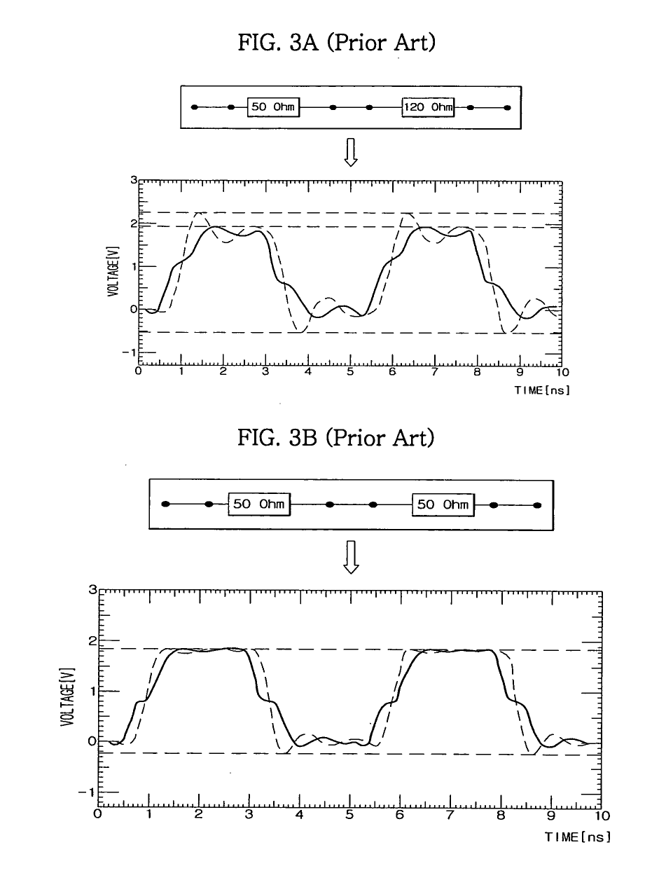

FIGS. 4A and 4B illustrate a plan view and a longitudinal cross-sectional view of an electric apparatus according to a first exemplary embodiment of the present invention, respectively;

FIG. 5A illustrates a plan view of an electric apparatus according to a second exemplary embodiment of the present invention, FIG. 5B illustrates a longitudinal cross-sectional view taken along a dotted line A shown in FIG. 5A, and FIG. 5C illustrates a longitudinal cross-sectional view taken along a dotted line B shown in FIG. 5A;

FIG. 6 illustrates a plan view of an electric apparatus according to a third exemplary embodiment of the present invention; and

FIGS. 7A and 7B illustrate a plan view and a longitudinal cross-sectional view of an electric apparatus according to a fourth exemplary embodiment of the present invention, respectively.

### DETAILED DESCRIPTION OF EMBODIMENTS

Reference will now be made in detail to exemplary embodiments of the present invention, examples of which are illustrated in the accompanying drawings, wherein like reference numerals refer to like elements throughout. Exemplary embodiments are described below to explain the present invention by referring to the figures.

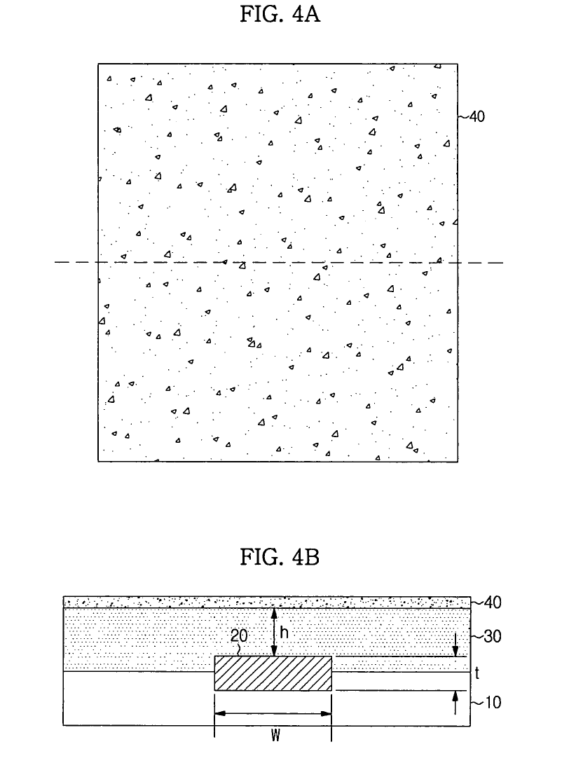

FIGS. 4A and 4B illustrate a plan view and a longitudinal cross-sectional view of an electric apparatus according to a first embodiment of the present invention, respectively.

In order to realize a high speed IC such as a digital signal processor (DSP) and a memory in an electric circuit mounted on a case, various signals must be grounded.

Accordingly, as shown in FIG. 4B which is a longitudinal cross-sectional view taken along a dotted line of FIG. 4A, after a signal line 20 is formed to transmit signals between electronic parts on a case 10, a specific amount of dielectric 30 is deposited on the case 10 and the signal line 20, and a ground portion 40 is uniformly stacked on an entire surface of the deposited dielectric 30.

In this case, when the electric apparatus according to the first embodiment is viewed from the top, as shown in FIG. 4A, only the ground portion 40 having a wide plate shape is seen.

An impedance of the electric apparatus according to the first exemplary embodiment can be obtained by the following equation 3.

$$Zo = \frac{87}{\sqrt{ɛ r + 1.41}} ln \frac{5.98 h}{0.8 w + t} \qquad [ Eq . 3 ]$$

where h represents a distance between the signal line 20 and the ground portion 40, Er represents a dielectric constant of the dielectric 30, w represents a line width of the signal line 20, and t represents a height (thickness) of the signal line 20.

Generally, since the line width w of the signal line 20 and the height t of the signal line 20 are fixed values, according to the above impedance equation, h and ∈r are adjustable variables. The impedance is inversely proportional to the dielectric constant ∈r and proportional to the distance h between the signal line 20 and the ground portion 40. Accordingly, in case of the electric apparatus according to the first exemplary embodiment, the impedance can be controlled by adjusting the distance h between the signal line 20 and the ground portion 40, that is, a height (thickness) of the dielectric 30 deposited on the case 10 and the signal line 20, or by changing the kind of the deposited dielectric (dielectric material).

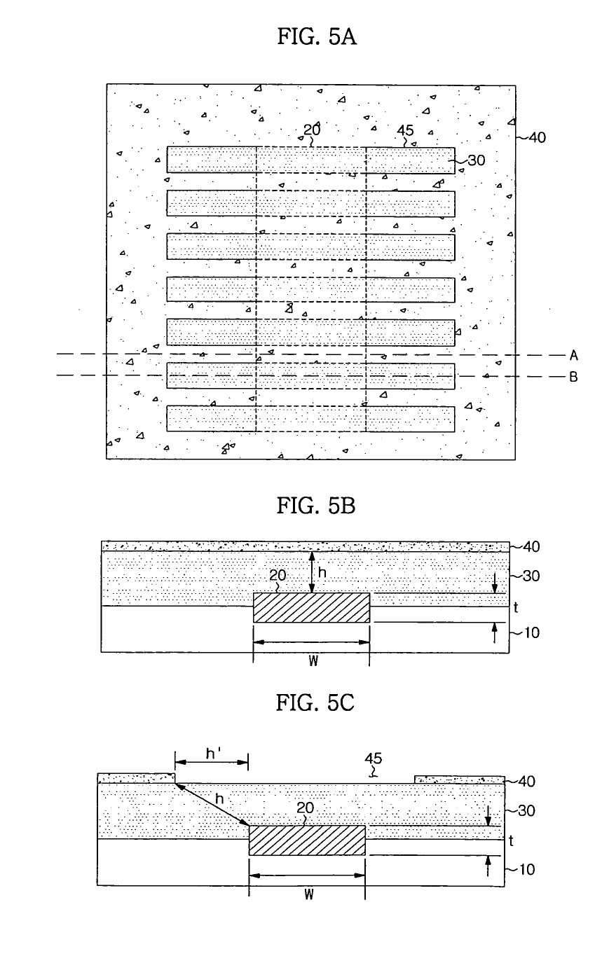

Hereinafter, an electric apparatus according to a second exemplary embodiment of the present invention will be described with reference to FIGS. 5A to 5C.

The first exemplary embodiment and the second exemplary embodiment of the present invention are different in a shape of the ground portion 40 disposed on the dielectric 30.

That is, as shown in FIGS. 4A and 4B, the electric apparatus according to the first exemplary embodiment of the present invention includes the wide plate-shaped ground portion 40 which is uniformly stacked on the entire surface of the deposited dielectric 30. On the other hand, as shown in FIG. 5A, the electric apparatus according to the second exemplary embodiment of the present invention includes a ground portion 40, which has a plurality of rectangular holes 45 having a longer horizontal length than a vertical length arranged in a stripe pattern. A portion of the dielectric 30 deposited below the ground portion 40 is exposed to the outside by the holes 45 formed on the ground portion 40.

When it is cut along a dotted line A shown in FIG. 5A, as shown in FIG. 5B, since the thin dielectric 30 is deposited on the signal line 20 and the ground portion 40 is formed directly on the dielectric 30, a distance h between the signal line 20 and the ground portion 40 is somewhat small. On the other hand, when it is cut along a dotted line B shown in FIG. 5A, as shown in FIG. 5C, since the ground portion 40 is not formed above the signal line 20, the distance h between the signal line 20 and the ground portion 40 is somewhat large.

As described above, the impedance is proportional to the distance h between the signal line 20 and the ground portion 40 according to Eq. 3. If the distance h between the signal line 20 and the ground portion 40 is small as shown in FIG. 5B (small value of h), the impedance is controlled to have a value (about 20˜30Ω) smaller than the impedance 50Ω of the normal circuit. On the other hand, if the distance h between the signal line 20 and the ground portion 40 is large due to the holes 45 formed on the ground portion 40 as shown in FIG. 5C (large value of h), the impedance is controlled to have a value (about 70˜80Ω) larger than the impedance 50Ω of the normal circuit.

Thus, when the signal line 20 passes below the stripe-shaped ground portion 40 as shown in FIG. 5A, the signal line 20 alternately passes through a portion where the ground portion 40 is formed above the signal line 20 (the impedance is controlled at about 20˜30Ω) and a portion where the ground portion 40 is not formed above the signal line 20 (the impedance is controlled at about 70˜80Ω). Accordingly, the impedance can be controlled at about 50Ω on the average, which is the impedance of the normal circuit.

As described above, the impedance can be controlled by adjusting the distance h between the signal line 20 and the ground portion 40. Generally, since the dielectric 30 deposited on the case 10 and the signal line 20 has a very small thickness, practically, the distance h is almost equal to a distance h′ in FIG. 5C (h is approximately equal to h′). Accordingly, in this exemplary embodiment, the impedance is controlled by adjusting the distance h′, that is, a longitudinal width of the holes formed on the ground portion 40.

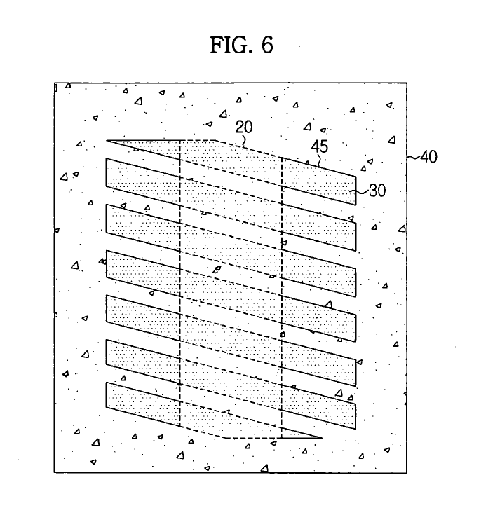

In this exemplary embodiment (second exemplary embodiment), as shown in FIG. 5A, the signal line 20 (disposed below the ground portion 40) is arranged perpendicularly (at an angle of 90 degrees) to the rectangular holes 45 formed on the ground portion 40 (or the stripe pattern of the ground portion 40). However, as shown in FIG. 6 (third exemplary embodiment), the signal line 20 may be arranged non-perpendicularly to the holes 45 formed on the ground portion 40 (or the stripe pattern of the ground portion 40).

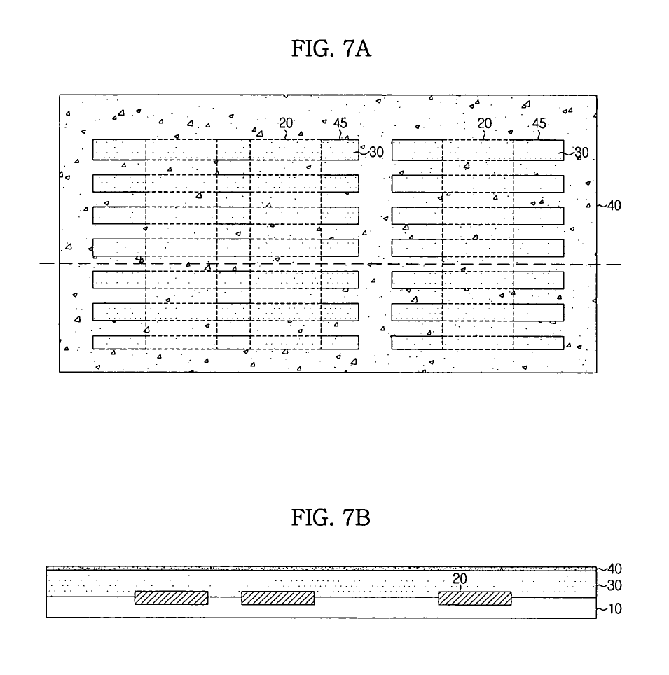

Further, in this exemplary embodiment (second exemplary embodiment), only one line (the signal line 20) is arranged on the case 10. However, as shown in FIGS. 7A and 7B (FIG. 7B is a longitudinal cross-sectional view taken along a dotted line of FIG. 7A), a plurality of signal lines 20 may be arranged on the case 10 (fourth exemplary embodiment).

Although a few exemplary embodiments of the present invention have been shown and described, it would be appreciated by those skilled in the art that changes may be made in these exemplary embodiments without departing from the principles and spirit of the invention, the scope of which is defined in the claims and their equivalents.

What is claimed is:

1. An electric apparatus comprising:
a case having a signal line which transmits signals between electronic parts;
a dielectric deposited on the case and the signal line; and
a ground portion disposed on the dielectric, wherein the ground portion is a predetermined distance from the signal line.

2. The electric apparatus of claim 1, wherein the dielectric has a surface and the ground portion is disposed on the entire surface of the dielectric.

3. The electric apparatus of claim 1, wherein the predetermined distance provides an impedance of about 50 ohms.

4. The electric apparatus of claim 1, wherein the predetermined distance provides an impedance of about 100 ohms.

5. An electric apparatus comprising:
a case having a signal line which transmits signals between electronic parts;
a dielectric deposited on the case and the signal line; and
a ground portion which is disposed on the dielectric and which has a plurality of holes.

6. The electric apparatus according to claim 5, wherein the holes have a width and the width of the holes is greater than the width of the signal line.

7. The electric apparatus according to claim 5, wherein the width of the holes is perpendicular to an arrangement direction of the signal line.

8. The electric apparatus according to claim 5, wherein the holes are non-parallel to an arrangement direction of the signal line.

9. The electric apparatus according to claim 5, wherein a longitudinal width of the holes is adjusted to control impedance of the electrical apparatus.

10. The electric apparatus according to claim 5, wherein a longitudinal width of the holes is adjusted to control impedance of the electrical apparatus to provide an average impedance of about 50 ohms.
